(19) United States
(12) Patent Application Publication
(10) Pub. No.: US 2016/0154309 A1
(43) Pub. Date: Jun. 2, 2016

(54) METHOD OF MANUFACTURING STRUCTURE ON SUBSTRATE

(71) Applicant: USHIO DENKI KABUSHIKI KAISHA, Tokyo (JP)

(72) Inventors: Daisuke YAJIMA, Yokohama-shi (JP); Kazuyuki TSURUOKA, Yokohama-shi (JP)

(73) Assignee: USHIO DENKI KABUSHIKI KAISHA, Tokyo (JP)

(21) Appl. No.: 14/953,068

(22) Filed: Nov. 27, 2015

(30) Foreign Application Priority Data
Dec. 2, 2014 (JP) 2014-244339

(51) Int. Cl. G03F 7/20; H01L 33/20; G02B 5/30; G03F 7/40; G02B 1/118; G02B 1/12; H01L 33/00; G03F 7/36

(52) U.S. Cl. CPC G03F 7/2022; H01L 33/005; H01L 33/20; G03F 7/36; G03F 7/40; G02B 1/118; G02B 1/12; G02B 5/3025

(57) ABSTRACT

A method manufactures a structure having a first fine pattern on a substrate. The method includes forming a resist layer on the substrate, dividing a laser beam into two branch beams, and causing the branch beams to cross each other at an interference angle thereby generating a first interference beam. The method also includes exposing the resist layer with the first interference beam. The method also includes producing a second interference beam from the branch beams such that the second interference beam crosses the first interference beam at a predetermined angle, and exposing the resist layer with the second interference beam. The method also includes removing those areas of the resist layer which are irradiated with the first and second interference beams, thereby forming a second fine pattern in the resist layer. The method also includes etching the substrate with the second fine pattern of the resist layer.

### TECHNICAL FIELD

The present invention relates to a method of manufacturing a structure on a substrate having a fine pattern formed on its surface, and also relates to such structure formed on the substrate.

### DESCRIPTION OF THE RELATED ART

There is an increasing demand for making a fine structure in an optical element (e.g., a polarizer and an antireflection element), a semiconductor light emitting element (e.g., a fluorescent light source and an LED (light emitting diode)), and other devices. A technology is developed to manufacture a fine structure in the order smaller order than a visible light wavelength (e.g., 100 nm or less than 100 nm).

One of the known methods for making a fine pattern in such subwavelength order is, for example, an exposure method using a stepper or electron beam lithography. Another method relies upon photolithography, which uses an X-ray having a shorter wavelength than an ultraviolet beam. Such method is disclosed in, for example, Non Patent Literature Document 1 (will be mentioned below). However, these methods are not suitable for mass production, and are not practiced as the methods for manufacturing the above-mentioned optical element, semiconductor light emitting element and similar devices.

In general, the electron beam lithography exposure and the X-ray lithography can only expose a limited size of surface at one time, and therefore its throughput is low. Thus, the electron beam lithography exposure and the X-ray lithography are not suitable for mass production. In particular, the electron beam lithography exposure directly exposes a work with the electron beam itself. Thus, the electron beam lithography exposure can achieve high precision processing such as in the order of several nm, but it requires a huge amount of processing time (e.g., several days) to finish the exposure if the work has a certain size (e.g., several mm×several mm).

The exposure method that uses the stepper is suitable for mass production, but the work must meet the SEMI (Semiconductor Equipment and Materials International) standard. Thus, if the work has a certain thickness or a bending portion, then the exposure method with the stepper cannot be applied. For example, the SEMI standard requires that an 8-inch Si substrate must have a thickness of 725±20 μm with a total thickness variation (TTV) being 10 μm. If the substrate does not meet these requirements, the stepper cannot expose the substrate. A substrate of the above-mentioned optical element, semiconductor light emitting element and similar devices may have a small diameter (e.g., between one and two inches), or may bend considerably because the surface of the substrate is coated with a functional material. The stepper cannot expose such substrate.

As described above, the existing technologies have limitations with regard to the throughput and the work shape. Thus, it is difficult for the existing technologies to make a fine structure on a substrate of various types of device.

To deal with such difficulties in recent years, there is proposed a method for making a fine structure by a nanoimprinting method (nanoimprint lithography: NIL). The nanoimprinting method sandwiches a work (e.g., resin or glass work) between a master mold and a substrate to transfer a fine concave-convex pattern from the master mold to the work.

### LISTING OF REFERENCES

### Non Patent Literature Documents

NON PATENT LITERATURE DOCUMENT 1: “Applied Physics,” Japan Society of Applied Physics, 2004, Vol. 73(4), p. 455-461.

### SUMMARY OF THE INVENTION

The NIL is studied intensively. If a master mold is prepared, a fine processing is easily carried out in a mass production line. This is an advantage of the NIL. In reality, however, the NIL has various problems because the NIL requires the contact between the work and the master mold every time the fine processing is carried out. Specifically, the shape of the master mold may change, the pattern may not be formed in a desired shape if bubbles are trapped when feeding the photoresist, and a fine concave-convex pattern may not be completely transferred to the work if particles are present between the concave-convex pattern and the work. In principle, the NIL is difficult to apply to the work if the work has a considerable bending portion. For these reasons, the NIL does not have a good yield in the mass production. Thus, the NIL is not suitable for a highly precise patterning.

In addition, the NIL has a cost issue. Because the work contacts the master mold every time the fine concave-convex pattern is transferred to the work in the NIL, the master mold is damaged or deteriorated. Thus, a periodical replacement of the master mold is needed. The master mold has a high-precision fine concave-convex pattern in its large surface, and a relatively expensive electron beam processing and/or a relatively expensive lithography patterning using a KrF stepper should be used with the master mold. Accordingly, a running cost becomes high if the NIL (master mold) is used in the mass production. Also, a new master mold should be prepared every time a design modification is made to a final product. Thus, the NIL is not suitable for a study purpose, and not suitable for production of many kinds of products in small quantities.

An object of the present invention is to provide a method of manufacturing a high-precision fine structure on a substrate at a low cost.

Another object of the present invention is to provide such fine structure on a substrate at a low cost.

According to one aspect of the present invention, there is provided a method of manufacturing a structure on a substrate. The method ultimately forms a first fine pattern (or a structure having a first fine pattern) on a surface of the substrate or a surface of a functional material layer. The functional material layer is formed on the substrate. The first fine pattern includes a plurality of convex portions and/or a plurality of concave portions arranged in an array. The method includes forming a photosensitive material layer on the surface of the substrate or the surface of the functional material layer. The method also includes dividing a single beam emitted from a coherent light source into at least two branch beams. The method also includes causing the branch beams to cross each other at a predetermined interference angle thereby generating a first interference beam that has interference fringes extending in a first longitudinal direction. The method also includes applying an exposure process to the photosensitive material layer with the first interference beam. The method also includes producing a second interference beam from the branch beams such that the second interference beam has interference fringes extending in a second longitudinal direction. The second longitudinal direction of the interference fringes of the second interference beam crosses the first longitudinal direction of the interference fringes of the first interference beam at a predetermined angle. The second interference beam has the same interference angle as the first interference beam. The method also includes applying the exposure process to the photosensitive material layer with the second interference beam after the step of applying an exposure process to the photosensitive material layer with the first interference beam. The method also includes removing those areas of the photosensitive material layer which are irradiated with the first and second interference beams (or those areas of the photosensitive material layer which are not irradiated with the first and second interference beams), after the exposure process with the first and second interference beams, thereby forming a second fine pattern in the photosensitive material layer. The method also includes applying an etching process to the substrate or the functional material layer with the second fine pattern of the photosensitive material layer, thereby creating the structure having the first fine pattern on the surface of the substrate or the surface of the functional material layer.

Thus, the method of manufacturing the structure on the substrate creates the fine pattern with the exposure process using the interference beams. The exposure process that uses the interference beams does not use a fine photomask when carrying out the fine exposure process. No elements contact the work during the exposure process. Therefore, it is possible to improve the yield in a mass production, as compared to a conventional nanoimprint method. Unlike the nanoimprint method, the method of the present invention does not need an expensive master mold. Therefore, the high-precision patterning process is carried out at a low cost. Accordingly, it is possible to manufacture a structure on the substrate that has a fine pattern at two-dimensional periods in the surface of the substrate (or in the surface of the functional material layer formed on top of the substrate) in an easy manner at high precision. The substrate having such structure thereon can be used in various applications, such as in an optical element and a semiconductor light-emitting element.

The method of manufacturing a structure on a substrate may further include, prior to applying the etching process, applying a heat treatment to the second fine pattern formed in the photosensitive material layer, in order to shape the second fine pattern to a desired fine pattern.

The heat treatment can shape the fine pattern to a desired fine pattern. Thus, it is possible to increase the accuracy of the ultimate fine pattern. When the fine pattern is a plurality of convex portions, the heat treatment can enlarge the size of each convex portion. Thus, it is possible to reduce the spacing between adjacent convex portions. In other words, the heat treatment can shape the second fine pattern to the fine pattern having a plurality of convex portions at a higher density than the second fine pattern. As a result, the structure on the substrate can have a plurality of convex portions at a high density.

The photosensitive material layer may be made from a material having a glass-transition temperature. The step of applying a heat treatment may include heating the second fine pattern at a temperature higher than a glass-transition temperature.

When the heat treatment heats the photosensitive material layer at a temperature higher than the glass-transition temperature, it is possible to naturally shape (deform) the fine pattern having anisotropy (e.g., each convex portion having an oval shape when viewed from the top) to a fine pattern having isotropy (e.g., each convex portion having a perfect circular shape when viewed from the top) by taking advantage of the surface tension. The resulting fine pattern in the photosensitive material layer may be used as a mask when the etching process is applied to the substrate (or the functional material layer disposed on the substrate). The etching process creates a precise moth eye structure on the substrate, with each moth eye having a perfect circular shape when viewed from the top.

In the method of manufacturing a structure on a substrate, the step of producing the second interference beam and the step of applying the exposure process to the photosensitive material layer with the second interference beam may be carried out such that the step of removing those areas of the photosensitive material layer can form the second fine pattern that has a plurality of convex elements and/or a plurality of concave elements in a square array. When the longitudinal direction of interference fringes of the second interference beam crosses the longitudinal direction of interference fringes of the first interference beam at 90 degrees, it is possible to form a moth eye structure in the square array on the photosensitive material layer (or in the structure on the substrate).

Alternatively, the step of producing the second interference beam and the step of applying the exposure process to the photosensitive material layer with the second interference beam may be carried out such that the step of removing those areas of the photosensitive material layer can form the second fine pattern that has a plurality of convex elements and/or a plurality of concave elements in a trigonal array. When the longitudinal direction of the interference fringes of the second interference beam crosses the longitudinal direction of the interference fringes of the first interference beam at 60 degrees, it is possible to form a moth eye structure in the trigonal array on the photosensitive material layer (or in the structure on the substrate). The moth eye structure in the trigonal array has a fine pattern with a greater density than the moth eye structure in the square array.

The method of manufacturing a structure on a substrate may further include producing a third interference beam from the branch beams such that the third interference beam has interference fringes extending in a third longitudinal direction, which crosses the first longitudinal direction of the interference fringes of the first interference beam at a second predetermined angle. The third interference beam has the same the interference angle as the first interference beam. The method may further include applying the exposure process to the photosensitive material layer with the third interference beam after applying the exposure process to the photosensitive material layer with the second interference beam. By applying the exposure process with the interference beam a plurality of times, it is possible to easily form a desired fine pattern in the photosensitive material layer.

The method of manufacturing a structure on a substrate may further include turning the substrate by the predetermined angle after the step of applying an exposure process to the photosensitive material layer with the first interference beam and before the step of applying the exposure process to the photosensitive material layer with the second interference beam. By turning the substrate, it is possible to easily cause the second longitudinal direction of the interference fringes of the second interference beam to cross the first longitudinal direction of the interference fringes of the first interference beam at the predetermined angle.

According to another aspect of the present invention, there is provided another method of manufacturing a structure having a first fine pattern on a surface of a substrate or a surface of a functional material layer. The functional material layer is formed on the substrate. The first fine pattern includes a plurality of convex portions and/or a plurality of concave portions. The method includes forming a first layer on the surface of the substrate or the surface of the functional material layer. The method also includes applying a patterning process to the first layer to form a second fine pattern in the first layer. The method also includes applying a heat treatment to the second fine pattern to shape the second fine pattern to a third fine pattern. The method also includes applying an etching process to the substrate or the functional material layer with the third fine pattern, thereby creating the structure having the first fine pattern on the surface of the substrate or the surface of the functional material layer.

This fine structure manufacturing method heat-treats the second fine pattern formed in the first layer on the substrate (or on the functional material layer) and shapes the second fine pattern to the third fine pattern. Thus, it is possible to improve the accuracy (preciseness) of the fine pattern in the first layer. The shaped fine pattern (i.e., the third fine pattern) is used as a mask when the etching process is applied to the substrate (or the functional material layer on the substrate). Thus, it is possible to precisely fabricate the structure on the substrate (or the functional material layer) that has a plurality of convex portions and/or a plurality of concave portions closely arranged in the surface of the substrate (or in the surface of the functional material layer).

According to a still another aspect of the present invention, there is provided a structure on a substrate, which is fabricated by the method of the first aspect or the second aspect. The resulting structure provides a precise and fine pattern on the substrate (or the functional material layer on the substrate).

The manufacturing method of the present invention performs the interference exposure, i.e., performs the exposure step with the interference beams. Thus, it is possible to form a highly precise fine pattern, which is made from a photosensitive material layer, at a low cost. Accordingly, it is possible to manufacture a substrate that has a structure, which has a highly precise fine pattern, formed on the surface of the substrate or on the surface of the functional material layer disposed on the substrate, at a low cost.

These and other objects, aspects and advantages of the present invention will become apparent to those skilled in the art from the following detailed description when read and understood in conjunction with the appended claims and drawings.

### BRIEF DESCRIPTION OF THE DRAWINGS

FIG. 1 illustrates a schematic configuration of an exposure device according to a first embodiment of the present invention.

FIG. 2 shows beams used in an exposure process according to the embodiment of the present invention.

FIG. 3 shows an interference pattern (interference fringes) used in first exposure.

FIG. 4 shows an interference pattern (interference fringes) used in second exposure.

FIG. 5A three-dimensionally illustrates exposure light intensity in the first exposure.

FIG. 5B two-dimensionally illustrates the exposure light intensity in the first exposure.

FIG. 5C three-dimensionally illustrates the exposure light intensity in the second exposure when an interference pattern is turned 90 degrees from FIG. 5A.

FIG. 5D two-dimensionally illustrates the exposure light intensity in the second exposure when the interference pattern is turned 90 degrees.

FIG. 5E three-dimensionally illustrates combined exposure light intensity.

FIG. 5F two-dimensionally illustrates the combined exposure light intensity.

FIG. 6 shows a resist pattern obtained when the first exposure and the second exposure are carried out, with the interference pattern being turned 90 degrees after the first exposure.

FIG. 7A is similar to FIG. 5A, and three-dimensionally illustrates the exposure light intensity in the first exposure.

FIG. 7B is similar to FIG. 5B, and two-dimensionally illustrates exposure light intensity in the first exposure.

FIG. 7C is similar to FIG. 5C, and three-dimensionally illustrates the exposure light intensity in the second exposure when the interference pattern is turned 60 degrees from FIG. 7A.

FIG. 7D is similar to FIG. 5D, and two-dimensionally illustrates the exposure light intensity in the second exposure when the interference pattern is turned 60 degrees.

FIG. 7E is similar to FIG. 5E, and three-dimensionally illustrate the combined light exposure intensity.

FIG. 7F is similar to FIG. 5F, and two-dimensionally illustrate the combined light exposure intensity.

FIG. 8 shows a resist pattern when the first exposure and the second exposure are carried out, with the interference pattern being turned 60 degrees after the first exposure.

FIG. 9 shows a resist pattern when the heat treatment is applied at an insufficient temperature. The resist pattern has a plurality of dots that are the same as FIG. 8.

FIG. 10 shows a resist pattern that has a plurality of dots which are properly shaped by the heat treatment.

FIG. 11 is a cross-sectional view of an exemplary resist pattern prior to the heat treatment.

FIG. 12 is a plan view of the resist pattern shown in FIG. 11.

FIG. 13 is a cross-sectional view of a resist pattern which is obtained after the dots in the resist pattern are shaped by the heat treatment.

FIG. 14 is a plan view of the resist pattern shown in FIG. 13.

FIG. 15 is a cross-sectional view of a resist pattern which is obtained after the dots in the resist pattern are shaped by the heat treatment at a higher temperature than FIG. 13.

FIG. 16 is a plan view of the resist pattern shown in FIG. 15.

FIGS. 17A to 17F show, in combination, a method of manufacturing a structure on a substrate.

FIG. 18 shows two curves of luminous intensity of a light emitting element, with one curve being obtained when a heat treatment is applied to a fine structure, and the other curve being obtained when no heat treatment is applied.

FIG. 19 illustrates a schematic configuration of an exposure device to a second embodiment of the present invention.

FIG. 20A shows a mechanism of an angle-adjustable mirror.

FIG. 20B shows the angle-adjustable mirror that is moved and turned by its mechanism.

FIG. 21 is a schematic view useful to describe a multi-beam interference exposure method.

### DETAILED DESCRIPTION OF THE INVENTION

Now, embodiments of the present invention will be described with reference to the accompanying drawings.

### First Embodiment

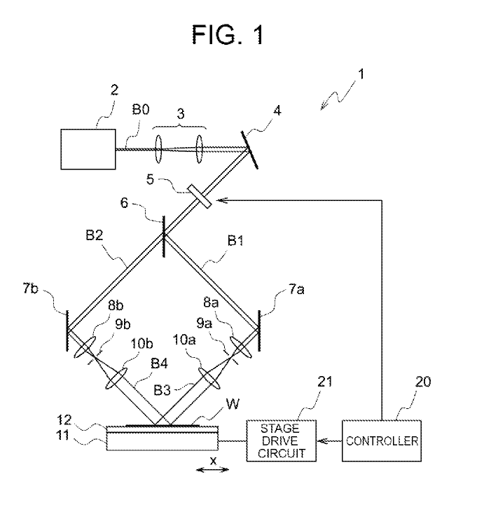

Referring to FIG. 1, an exposure device 1 of this embodiment will be described. The exposure device 1 includes a light source 2, a beam expander 3, a bring-down mirror 4, a shutter 5, a beam splitting element 6, turn-around mirrors 7a and 7b, light condensing lenses 8a and 8b, pin hole elements 9a and 9b, and collimator lenses 10a and 10b. The exposure device 1 also includes a stage 11, a suction table 12, a controller 20, and a stage drive circuit 21.

The light source 2 is a coherent light source that emits coherent light. For example, the light source 2 is a diode-pumped (LD-pumped) solid-state laser that emits a laser beam at a predetermined wavelength λ. The predetermined wavelength λ is, for example, 266 nm. The laser beam B0 emitted from the light source 2 is expanded by the beam expander 3, and the laser beam has an enlarged beam diameter. Then, the optical path of the laser beam is altered by the bring-down mirror 4.

The shutter 5 is configured to block passage of the laser beam therethrough when the shutter 5 is in an ON condition, and allow the laser beam to pass therethrough when the shutter 5 is in an OFF condition. The shutter 5 is disposed between the mirror 4 and the beam splitting element 6. Opening and closing (i.e., OFF and ON) of the shutter 5 is controlled by the controller 20.

The beam splitting element 6 is configured to split a single laser beam BO into two laser beams B1 and B2. The beam splitting element 6 is a concave-convex diffraction element that has a fine concave-convex shape in its surface, which is made from, for example, quartz. The diffraction takes place by taking advantage of the fine concave-convex shape.

The two laser beams B1 and B2, which are produced by the beam splitting element 6, change the optical paths respectively at the turn-around mirrors 7a and 7b, and are incident to the light condensing lenses 8a and 8b respectively. The two laser beams B1 and B2 may be referred to as “branch beams.”

After the light condensing at the light condensing lens 8a, the laser beam is incident to the pin hole 9a such that the laser beam has an enlarged beam diameter. Then, the laser beam is collimated by the collimator lens 10a. In this manner, the laser beam B3, which is a collimated beam, is obtained. Likewise, after the light condensing at the light condensing lens 8b, the laser beam is incident to the pin hole 9b such that the laser beam has an enlarged beam diameter. Then, the laser beam is collimated by the collimator lens 10b. In this manner, the laser beam B4, which is a collimated beam, is obtained.

The pin holes 9a and 9b serve as the spatial filters. The pin holes 9a and 9b are used to remove (eliminate) irregularities or disturbances in the beam wave front, which are generated when the beams travel from the light source 2 to the light condensing lenses 8a and 8b. The collimating lenses 10a and 10b are used to allow the laser beams to have an ideal flat wave front. Thus, the laser beams become plane waves.

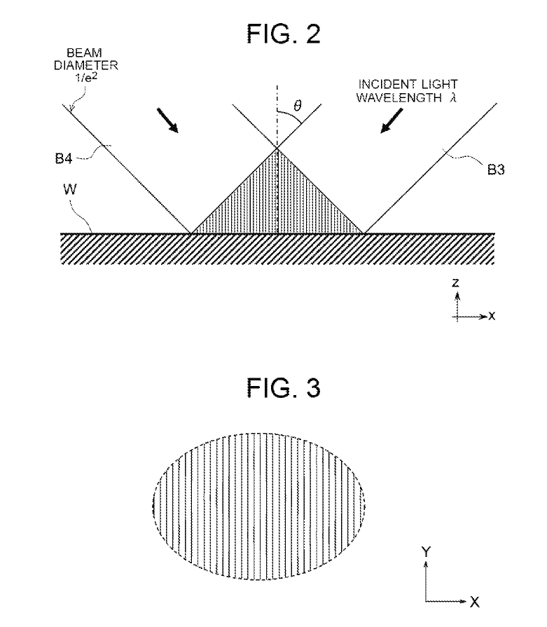

As shown in FIG. 2, the two laser beams B3 and B4 cross each other at a predetermined interference angle 2θ (2 theta). Thus, the two laser beams B3 and B4 create, in combination, interference fringes on the work (substrate) W because the two laser beams B3 and B4 interfere with each other. In other words, the two laser beams B3 and B4 creates an interference beam on the work W. The interference beam is used as the exposure beam to be applied to the work W in an exposure process. As such, one exposure can transfer a stripe pattern (line-and-spacing pattern) on the work W.

Therefore, the optical system that includes the beam expander 3, the bring-down mirror 4, the shutter 5, the beam splitting element 6, the turn-around mirrors 7a and 7b, the light condensing lenses 8a and 8b, the pin holes 9a and 9b and the collimating lenses 10a and 10b splits the beam emitted from the light source 2 into the two beams, and causes the two beams to cross each other at the interference angle 20 such that the interference beam is generated. The optical system has a pair of reflection mirrors 7a and 7b, a pair of condensing lenses 8a and 8b, a pair of pin holes 9a and 9b, and a pair of collimating lenses 10a and 10b between the beam splitting element 6 and the work W. This configuration guides and shapes the two laser beams, which are produced by the beam splitting element 6, such that the two laser beams reach the work W respectively, and interference with each other on the work W.

It should be noted that the beam diameter (1/e²) of each of the laser beams B3 and B4 may be decided arbitrarily by changing the magnifications at the beam expander 3, the associated light condensing lens 8a, 8b, and the associated collimating lens 10a, 10b. The beam diameter may be decided appropriately under given conditions such as a purpose of the exposure device 1.

Referring back to FIG. 1, the work W is secured on the suction table 12 disposed on the stage 11. The work W is, for example, a substrate on which a photosensitive material layer (e.g., photoresist layer) is formed. Alternatively, the work W may be a substrate that has a functional material layer on an upper surface of the substrate, and a photosensitive material layer on an upper surface of the functional material layer.

The work W is exposed by the interference beams and developed. As a result, a fine pattern is formed on (in) the photosensitive material layer (e.g., photoresist layer). The fine pattern includes a plurality of projections and/or recesses arranged in the photosensitive material layer. If the resist applied on the substrate is a positive resist, those portions of the resist which are irradiated with the interference beam dissolve in the developing liquid. When the positive resist is used, and the above-described exposure process and the development process are carried out, then those portions of the resist which are not irradiated with the interference beam remain in the resist pattern. On the other hand, if the resist is a negative resist, those portions of the resist which are irradiated with the interference beam cross-link and do not dissolve in the developing liquid. When the negative resist is used, and the exposure process and the development process are carried out, then the resulting resist pattern has the irradiated portions remaining after the development.

The stage 11 can move in the X-direction and Y-direction in parallel to the surface of the work W. The X-direction is the right-left direction in FIG. 1. The Y-direction is a direction perpendicular to the drawing sheet of FIG. 1. The controller 20 controls the stage drive circuit 21 to move the stage 11 in the X-direction and/or the Y-direction. Thus, the work W can move in the X-direction and the Y-direction upon movements of the stage 11 in the X-direction and the Y-direction.

In this embodiment, the exposure is applied to the work W a plurality of times. In the first exposure, the work W is irradiated with, for example, the interference beam that has interference fringes (interference pattern) shown in FIG. 3. The interference pattern of FIG. 3 is a stripe pattern, with the stripe extending in the Y-direction. In the second and subsequent exposure, the stripe interference pattern is turned by a predetermined angle δ from the pattern shown in FIG. 3, and the work W is irradiated with such interference pattern (second interference pattern).

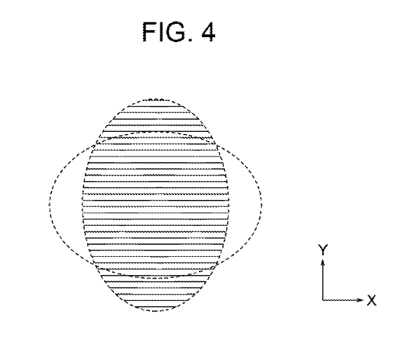

When the stripe interference pattern of FIG. 3 is turned by 90 degrees in order to perform the second and subsequent exposure, the second interference pattern becomes a stripe interference pattern as shown in FIG. 4, with the stripe extending in the X-direction. This interference pattern is applied to the work W. Accordingly, the work W is irradiated with the first interference pattern (first interference beam) and the second interference pattern (second interference beam) in an overlapping manner.

It should be noted that the turning angle δ of the interference pattern is not limited to 90 degrees. Specifically, the turning angle δ may be set to any suitable value from 0 degree to 90 degrees (0°δ≦90°). It is possible to change the shape of the second interference pattern to be applied to the work W by changing the turning angle δ.

It should also be noted that in the second and subsequent exposure the interference pattern may be turned or the stage 11, which supports work W thereon, may be turned. Preferably the stage 11 is turned because turning the stage 11 is easier.

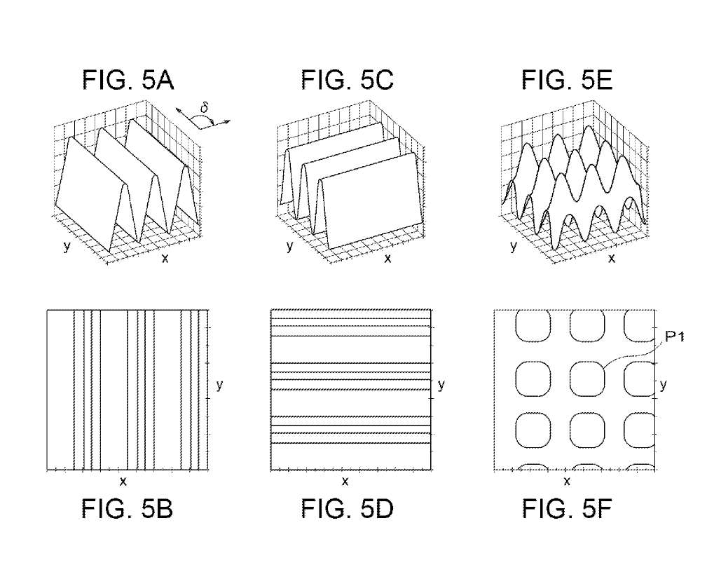

FIGS. 5A and 5B show a calculated distribution of an exposure light intensity in the first exposure. FIGS. 5C and 5D show a calculated distribution of the exposure light intensity in the second exposure when the interference pattern is turned 90 degrees from the first exposure (δ=90 degrees). FIGS. 5E and 5F show the calculated distribution of the combined exposure intensity of the first and second exposure.

The combined exposure intensity is obtained by performing the first and second exposure in the overlapping manner. FIGS. 5A, 5C and 5E schematically show the intensity distribution three-dimensionally, and FIGS. 5B, 5D and 5F schematically show the intensity distribution two-dimensionally, respectively. The interference fringes of the first exposure cross the interference fringes of the second exposure at 90 degrees. In other words, the longitudinal direction of the interference pattern in the first exposure crosses the longitudinal direction of the interference pattern in the second exposure at right angles. As a result, the combined pattern of the first and second interference beams has a lattice shape (FIG. 5B+FIG. 5D=FIG. 5F) when viewed from the top (i.e., in the X-Y plane). Therefore, as shown in FIG. 5F, each of those portions P1 which are not irradiated with the interference beams has a substantially circular shape in the X-Y plane. The arrangement of dots P1 is referred to as “dot pattern.”

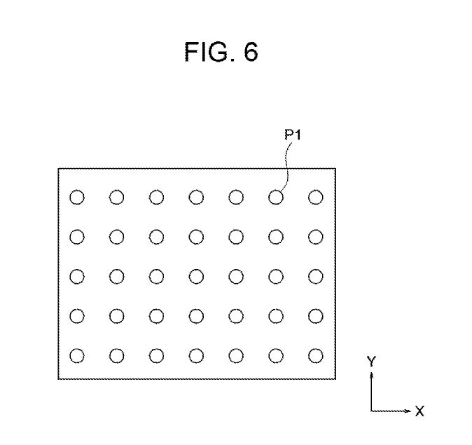

Thus, if the resist is a positive resist, the resulting resist pattern that is obtained after the development has a plurality of columns (circular cylinders) remaining in the resist pattern. In this case, as shown in FIG. 6, a fine pattern has a plurality of columns (dots) P1 that are arranged in a square array.

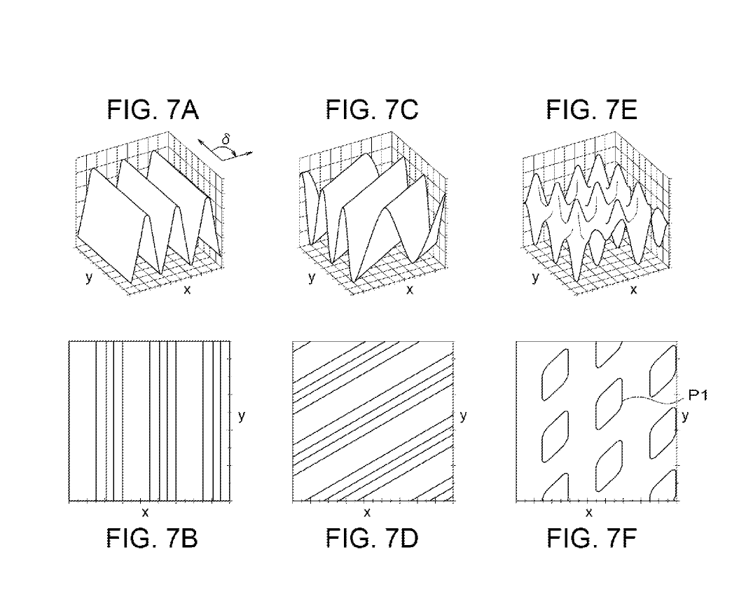

FIGS. 7A to 7F are similar to FIGS. 5A to 5F, and show the exposure light intensities when the interference pattern used in the first exposure is turned 60 degrees and used in the second exposure (δ=60 degrees). FIGS. 7A and 7B show a calculated distribution of an exposure light intensity in the first exposure. FIGS. 7C and 7D show a calculated distribution of the exposure light intensity in the second exposure. FIGS. 7E and 7F show the calculated distribution of the combined exposure light intensity of the first and second exposure. FIGS. 7A, 7C and 7E schematically show the intensity distribution three-dimensionally, and FIGS. 7B, 7D and 7F schematically show the intensity distribution two-dimensionally, respectively. The longitudinal direction of the interference pattern in the first exposure crosses the longitudinal direction of the interference pattern in the second exposure at 60 degrees. Then, each of those portions (dot pattern) P1 which are not irradiated with the interference beams has a substantially oval shape in the X-Y plane.

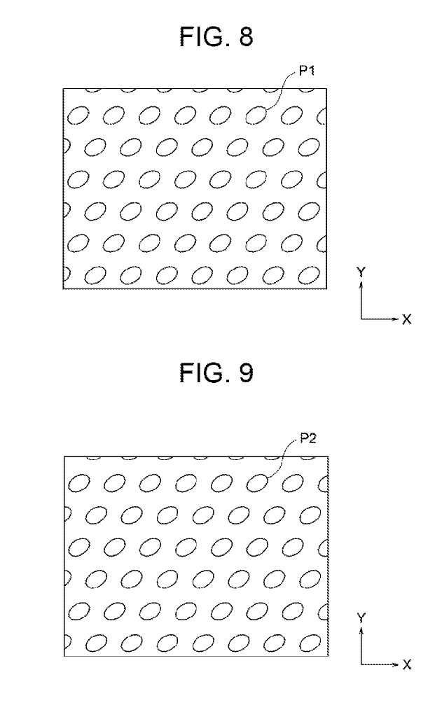

Thus, if the resist is a positive resist, the resulting resist pattern that is obtained after the development has a plurality of oval columns (elliptic cylinders) remaining in the resist pattern. In this case, as shown in FIG. 8, a fine pattern has a plurality of oval columns (dots) P1 that are arranged in a trigonal array.

As described above, when the interference pattern used in the first exposure is turned 60 degrees and used in the second exposure (FIG. 8), the dot pitch is reduced, as compared to when the interference pattern used in the first exposure is turned 90 degrees and used in the second exposure (FIG. 6). Thus, it is possible to fabricate a resist pattern having a desired dot density in the X-Y plane by altering the angle difference δ of the interference pattern between the first exposure and the second exposure.

In this embodiment, a heat treatment may be applied to the obtained resist pattern such that the dots in the pattern have a desired shape.

The inventors found that the pattern (dot) P can have a perfect circular shape if a heat treatment is properly applied to the resist pattern obtained after the above-described exposure and development. In this embodiment, therefore, the resist pattern is shaped to a perfect circle by heating the resist pattern at a temperature that is higher than the glass-transition temperature of the resist.

FIG. 9 shows a result, which was obtained after the heat treatment was applied to the resist pattern P1 shown in FIG. 8 at a temperature below the glass-transition temperature of the resist. The glass-transition temperature of the resist was approximately between 140 degrees C. and 150 degrees C. The heat treatment was applied to the resist at the temperature of 130 degrees C. for ten minutes. As illustrated in FIG. 9, the resist pattern P2, which was obtained after the heat treatment, did not change from the resist pattern P1 when the heat treatment was carried out at a temperature below the glass-transition temperature. Thus, no shaping took place.

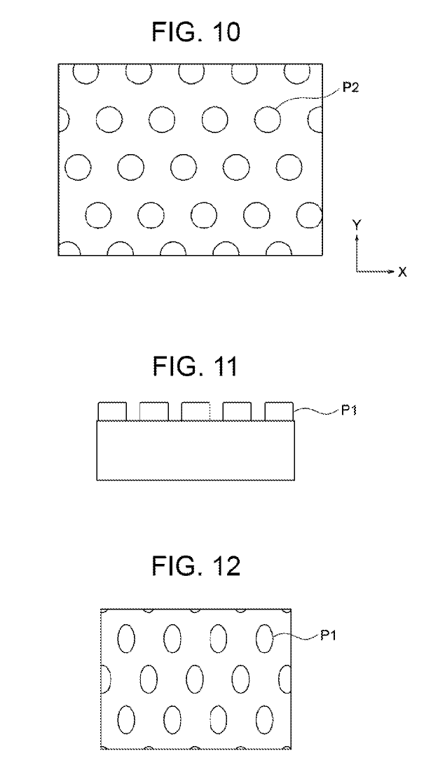

On the contrary, when the heat treatment was applied to the resist pattern P1 shown in FIG. 8 at a temperature over the glass-transition temperature of the resist, the resist pattern P1 was shaped to a desired shape. The result is shown in FIG. 10.

The glass-transition temperature of the resist was approximately between 140 degrees C. and 150 degrees C. The heat treatment was applied to the resist at the temperature of 200 degrees C. (heating temperature) for ten minutes (heating time). As mentioned above, when the heat treatment was carried out at the temperature over the glass-transition temperature, the resist pattern was shaped to a desired shape, i.e., the pattern P2 has had a perfect circular shape after the heat treatment as shown in FIG. 10. In this manner, it is possible to shape the resist pattern having the oval shape to a resist pattern having a perfect circular shape by the heat treatment. Therefore, it is possible to obtain the perfect circular dot pattern in the trigonal array.

As described above, it is possible to fabricate the resist pattern having a desired dot density in the surface of the resist (X-Y plane) by altering the turning angle (angle difference) δ of the interference pattern between the first exposure and the second exposure. Thus, it is possible to manufacture the resist pattern having perfect circular dots at a desired density by carrying out the exposure a plurality of times with an appropriate angle difference between the first interference beam and the second interference beam, and carrying out the heat treatment under appropriate conditions after the development.

The resist, which is obtained after the heat treatment in the above-described manner (FIG. 10), is used as a mask, and an etching is applied to the substrate, which has the resist on top thereof, or the functional material layer disposed on the substrate. As a result, those portions of the substrate or the functional material layer which are not covered with the resist are removed by the etching process. Accordingly, the surface of the substrate or the surface of the functional material layer has a convex structure. This convex structure has a plurality of convex portions at two-dimensional periods. This convex structure is a moth eye structure. Therefore, it can be said that the substrate has a moth eye structure thereon. As described above, each dot in the resist pattern after the heat treatment is shaped to a perfect circular shape. Accordingly, it is possible to fabricate a highly precise moth eye structure with each dot (eye) having a perfect circular shape at its bottom.

It should be noted that the heating conditions in the heat treatment, such as the heating temperature and the heating time, may be adjusted to alter the size of the dot(s) in the resist pattern.

FIG. 11 illustrates a cross-sectional view of an exemplary resist pattern prior to the heat treatment. For example, when the turning angle (angle difference) δ of the interference pattern between the first exposure and the second exposure is 60 degrees, the resist pattern has a plurality of oval dots P1 arranged as shown in FIG. 12, when viewed from the top. These dots P1 are arranged in a trigonal array in the X-Y plane. Thus, the shape of each of the dots (fine structure) P1 prior to the heat treatment is an elliptic column when the turning angle of the interference pattern between the first exposure and the second exposure is 60 degrees. The vertical cross-sectional view of each column P1 is approximately rectangular, as shown in FIG. 11.

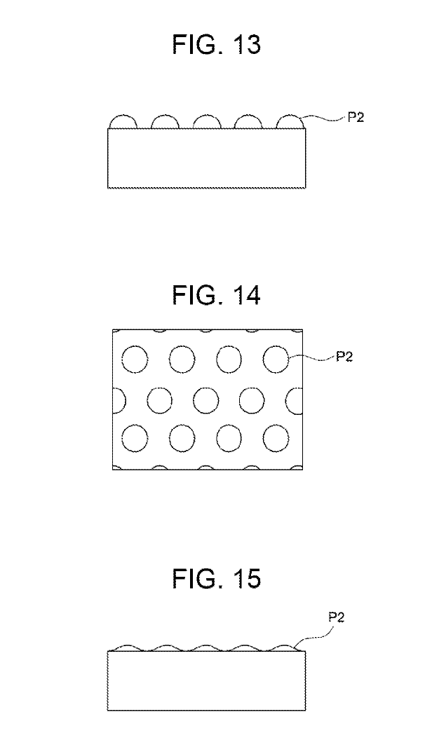

The heat treatment is applied to the resist pattern shown in FIG. 11. Then, the fine structure P1 is shaped to a fine structure P2 having a hemispherical shape, as shown in FIG. 13. FIG. 13 is a cross-sectional view. The fine structure P2 has a peak and expands downward from the peak toward the substrate, with its diameter also increasing. The heat treatment is carried out at the heating temperature of 185 degrees C. for ten minutes. The shape of the fine structure P2 in the X-Y plane becomes a perfect circle, as shown in FIG. 14. Accordingly, spacing between neighboring dots (fine structures) P2 in the resist pattern is reduced, as compared to FIG. 12. As such, the resist pattern has a plurality of dots P2 closely arranged in an isotropic array.

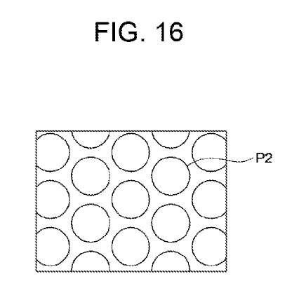

If the conditions of the heat treatment are changed, i.e., the heat treatment is carried out at the heating temperature of 215 degrees C. for ten minutes, then a resist pattern shown in FIG. 15 is obtained after the heat treatment. FIG. 15 shows a cross-sectional view of the resist pattern. The fine structure P2 shown in FIG. 15, which results after the heat treatment, has a shorter hemispherical shape than the fine structure P2 shown in FIG. 13, which also results after the heat treatment. The shape of the fine structure P2 (FIG. 15) in the X-Y plane is depicted in FIG. 16. The perfect circular shape of the fine structure P2 shown in FIG. 16 has a larger diameter than the perfect circular shape of the fine structure P2 shown in FIG. 14.

As understood from the foregoing, when the heating temperature of the heat treatment is raised, the dot diameter becomes larger even if the heating time is unchanged. Thus, the spacing between neighboring fine structures (dots) becomes smaller. In other words, the distance between the adjacent fine structures (dots P2) decreases in the resist pattern, and the fine structures are arranged close(r) to each other.

As described above, the dot diameter can be altered upon the heat treatment, by altering the heating conditions of the heat treatment. This can change the density of the fine structures to be made in the surface of the substrate (or the functional material layer on the substrate).

It should be noted that although the heating temperature is altered in the foregoing, the heating time may additionally be altered or the heating time may be altered instead of the heating temperature. It is also possible to change the dot diameter upon the heat treatment, if the heating time is changed. In order to obtain a desired dot diameter (or a desired dot density of the resist pattern), the heating conditions may be appropriately altered or adjusted in accordance with the material of the resist, the material of the substrate located under the resist, or other factors.

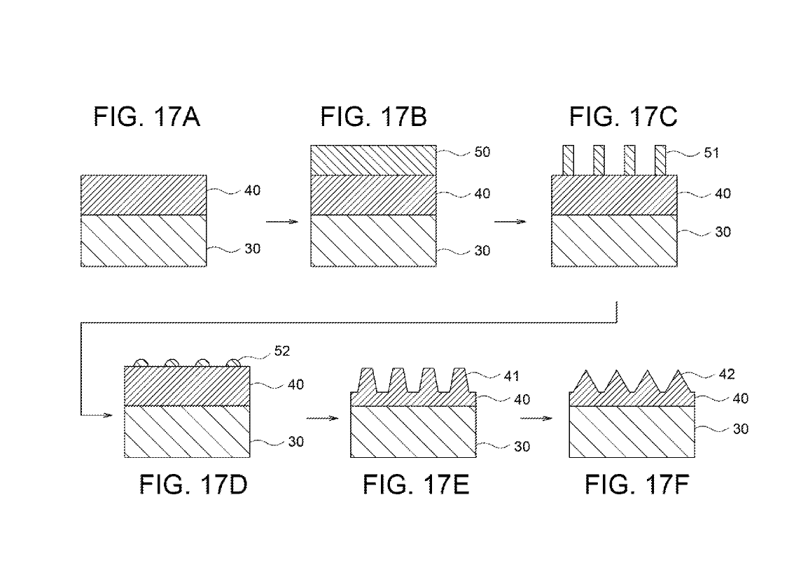

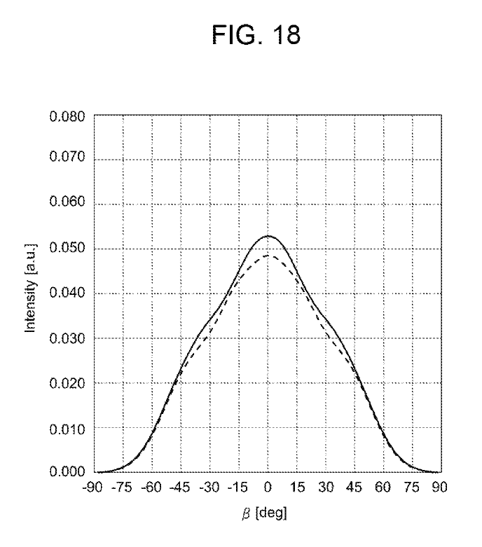

FIGS. 17A to 17F show, in combination, a method of manufacturing a substrate having a moth eye structure thereon. Referring to FIG. 17A, a substrate 30 is prepared. The substrate 30 has a functional material layer 40 thereon. The substrate 30 is a silica substrate (SiO₂) or the like. The functional material layer 40 is made from, for example, zirconia (ZrO₂). The functional material layer 40 is formed on the substrate 30 by a deposition method such as sputtering.

It should be noted that the material of the substrate 30 and the material of the functional material layer 40 may be appropriately decided in accordance of use of a final product or other factors.

The first step of the manufacturing method is shown in

FIG. 17B. In the first step, a photosensitive material layer (e.g., photoresist layer) 50 is formed on the functional material layer 40. In the second step of the manufacturing method, the above-described two-beam interference exposure is applied to the photoresist 50 a plurality of times in order to expose the photoresist 50.

In the third step of the manufacturing method, the exposed photoresist 50 is developed. Thus, those portions of the photoresist 50 which are irradiated with the interference beams are removed. Then, a fine pattern 51 is created, as shown in FIG. 17C. The fine pattern 51 has a dot pattern.

In the fourth step of the manufacturing method, the heat treatment is applied to the fine pattern 51 of the photoresist 50, which is obtained in the third step. This is a step of shaping the fine pattern 51. The oval shape of each dot in the fine pattern 51 is shaped to a circular shape by the shaping step. During the shaping step, the heat treatment is performed with, for example, a hot plate. As a result, the fine pattern 52 shown in FIG. 17D is obtained. The fine pattern 52 has a hemispherical shape in its vertical cross-sectional view.

In the fifth step of the manufacturing method, the fine pattern 52, which is obtained in the fourth step, is used as a mask to carry out the etching to the functional material layer 40. Subsequently, the fine pattern 52 of the photoresist is removed to obtain the fine pattern 41 in the functional material layer as shown in FIG. 17E.

In the final step of the manufacturing method, the sputtering is applied to the fine pattern 41 of the functional material layer, which is obtained in the fifth step. As a result, the substrate has a moth eye structure 42 of the functional material as shown in FIG. 17F. In this manner, the structure disposed on the substrate having the moth eye structure 42 is obtained.

In the exemplary method shown in FIGS. 17A-17F, the fine pattern is formed on the surface of the functional material layer 40 disposed on the substrate 30. It should be noted that the present invention is not limited in this regard. For example, the fine pattern 52 of the photoresist 50 may be formed on the surface of the substrate 30, and the fine pattern 52 may be used as the mask to carry out the etching to the substrate 30. Then, it is possible to form the moth eye structure on the surface of the substrate 30.

In the example shown in FIGS. 17A-17F, the photosensitive material layer (e.g., photoresist layer) 50 is formed on the upper surface of the functional material layer 40, and the exposure and the development are carried out to the photosensitive material layer to obtain the fine resist pattern. Then, the heat treatment is applied to the fine resist pattern to shape the resist pattern. It should be noted that the present invention is not limited in this regard. For example, a layer (e.g., resin layer having the glass-transition temperature) 50 may be formed on the surface of the functional material layer 40 disposed on the substrate 30 or formed on the surface of the substrate 30. The fine pattern 51 may be formed on the layer 50 by, for example, the NIL or a hot embossing process, not by the exposure and the development. Then, the heat treatment may be applied to the fine pattern 51 to shape the fine pattern 51 such that the fine pattern 52 is obtained. The fine pattern 52 may be used as the mask when etching the functional material layer 40 or the substrate 30.

The substrate having the moth eye structure thereon, which is fabricated in the above-described manner, may be used as an optical element such as a polarizer and an antireflection element. Alternatively, the substrate having the moth eye structure thereon may be used as a semiconductor light emitting element, such as an LED and a fluorescent light source, or other type of devices.

As described above, in this embodiment, the single beam emitted from the coherent light source is divided into two beams, and the two beams are forced to cross each other at the predetermined interference angle such that the interference beams are produced. These interference beams are used to expose the photoresist. In the exposure process, the two-beam interference exposure is carried out a plurality of times. In the second and subsequent interference exposure, the longitudinal direction of the interference fringes applied to the photoresist is turned such that the longitudinal direction of the interference fringes of the second interference exposure intersects the longitudinal direction of the interference fringes applied to the photoresist in the first interference exposure at the predetermined angle. After the exposure, the development process is applied to the resist pattern to obtain the fine resist pattern.

The two-beam interference exposure does not use a fine photomask, but is still able to expose an object (work) with a fine pattern. In the two-beam interference exposure, nothing contacts the work. Thus, the two-beam interference exposure improves the yield, as compared to the NIL or the like which requires the contact between the work and the master mold every time the fine processing is carried out (every time the fine concave-convex pattern is transferred to the work from the master mold).

Also, the two-beam interference exposure can expose the work at a very deep depth of focus. Thus, the flatness of the work does not matter in the two-beam interference exposure.

For example, the nanoimprint method may damage or break the work if the work has a bending portion. The transfer process in the nanoimprint method may become insufficient if the work has a bending portion. In view of such fact, the two-beam interference exposure is employed in the embodiment of the present invention. The two-beam interference exposure is employed because the exposure can precisely be carried out even if the work has a bending portion.

In the nanoimprint method, the frequent contact between the work and the master mold deteriorates (damages) the master mold. Thus, the master mold needs to be monitored and replaced. On the other hand, the two-beam interference exposure does not need such monitoring and replacement. The two-beam interference exposure can ensure the stable quality without such monitoring and replacement. Furthermore, unlike the nanoimprint method, the two-beam interference exposure does not need a master mold, which is expensive and consumable. Thus, the two-beam interference exposure can reduce the cost.

It is possible to improve the accuracy of the resist pattern by heat treating the fine pattern, which is obtained after the development process, and shaping the fine pattern. If the heat treatment is carried out at a temperature over the glass-transition temperature, then the fine pattern having anisotropy is naturally (automatically) shaped to the fine pattern having isotropy due to the surface tension.

Thus, the fine projections (convex portions) and/or recesses (concave portions) are arranged on the work at two-dimensional periods by carrying out the etching process with the above-described photoresist. The work can therefore have a fine structure that has a regulated shape. In particular, when the resist pattern is a dot pattern, it is possible to fabricate a fine structure having a highly precise moth eye structure.

FIG. 18 illustrates two distribution curves of luminous intensity of the light emitting element that has a moth eye structure thereon. FIG. 18 shows that the luminous intensity distribution curve changes with the shape of the moth eye structure. In this drawing, the solid line indicates the luminous intensity when the moth eye structure has a perfect circular shape in the trigonal array, which is obtained when the heat treatment is applied. The broken line indicates the luminous intensity when the moth eye structure has an oval shape in the trigonal array, which is obtained when no heat treatment is applied. It is confirmed from FIG. 18 that the light intensity at an angle β=0 and in the vicinity thereof is increased by shaping the moth eye structure from the ellipse to the perfect circle in the heat treatment. The solid line curve draws a line above the broken line curve in FIG. 18. The angle β is a light emitting angle from the light emitting element.

In this embodiment, the arrangement of the dots in the resist pattern can be altered by altering the turning angle δ of the interference pattern from the first exposure to the second exposure in the interference exposure step. In addition, the shape of the resist pattern can be altered by altering the heating conditions of the heat treatment. Thus, it is possible to manufacture a moth eye structure that has a desired arrangement and a desired dot intensity in the X-Y plane.

It should be noted that the material of the substrate, on which the fine structure is provided, may be decided in accordance with use of the substrate. The substrate having the moth eye structure thereon, which is manufactured by the above-described embodiment, may be used as a master mold in the nanoimprint method.

### Second Embodiment

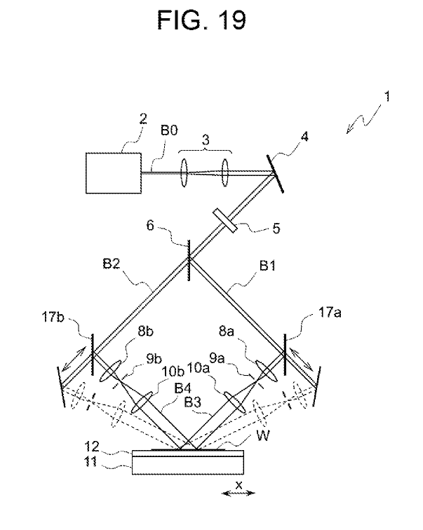

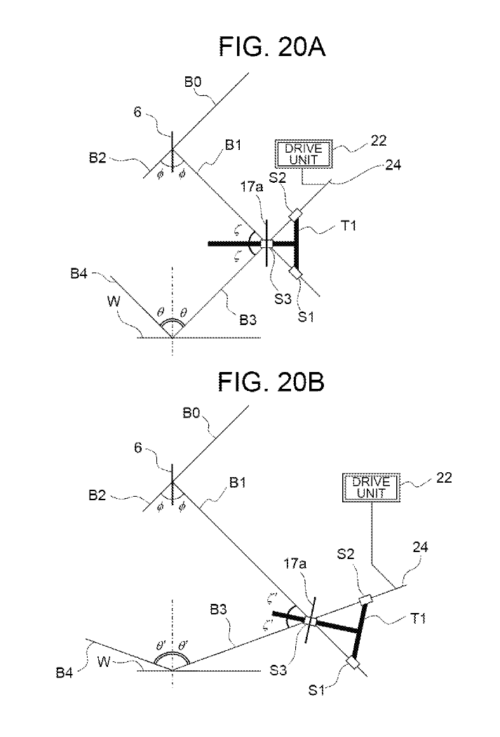

A second embodiment of the present invention will be described below with reference to FIGS. 19, 20A, and 20B.

The second embodiment is similar to the first embodiment except the turn-around mirrors 7a and 7b of the first embodiment being replaced with turn-around mirrors 17a and 17b, respectively in the second embodiment.

The turn-around mirrors 17a and 17b in the second embodiment are angle-adjustable mirrors whereas the turn-around mirrors 7a and 7b in the first embodiment are stationary mirrors. In the following description, the same reference numerals and symbols are used to designate the same components in the first and second embodiments.

FIG. 19 shows a schematic configuration of the exposure device 1 of the second embodiment.

Each of the angle-adjustable mirrors 17a and 17b of the exposure device 1 is configured to be able to change the angle of the light incident plane. By changing the angle of the light incident plane of each of the mirrors 17a and 17b, the interference angle 2θ is changed to a desired angle. As the interference angle 2θ changes, the line pitch in the interference pattern (stripe pattern) formed on the substrate changes.

FIGS. 20A and 20B illustrate the mirror 17a and a mechanism for changing the angle of the mirror 17a. The mirror 17b is equipped with the same mechanism as the mirror 17a. The mirror 17a has the same configuration as the mirror 17b.

The mirror 17a is a component for adjusting (changing) the interference angle θ to a desired angle θ′. The mirror 17a moves along a straight line defined by the beam B1, which is one of the two branch beams prepared at the beam splitter 6. The mirror 17a can also change its angle (inclination) about an axis that extends through its center in a direction perpendicular to the drawing sheet of FIG. 20A. The beam B1 is reflected by the mirror 17a and becomes the reflection beam B3 (i.e., mirror-reflected beam). The reflection beam B3 is directed to a predetermined location on the work W. The mirror-reflected beam B4 from the mirror 17b (not shown in FIG. 20A) combines (interferes) with the mirror-reflected beam B3 on the work W to create the interference fringes (interference beam). The normal line from the mirror 17a equally divides the angle between the branch beam B1 and the mirror-reflected beam B3 in FIG. 20A.

A method of adjusting the interference angle θ of the beam B3 while maintaining the positional relation between the normal line from the mirror 17a and the reflecting plane of the mirror 17a, for example, includes preparing a T-shaped frame T1, as shown in FIGS. 20A and 20B, and preparing a mechanism that uses (actuates) the T-shaped frame T1. The frame T1 has three sliders S1, S2 and S3. The slider S1 moves along the straight line defined by the branch beam B1 (diagonally downward to the right in FIG. 20A), and the slider S2 moves along the straight line defined by the mirror-reflected beam B3 (diagonally upward to the right in FIG. 20A). The slider S3 moves along the frame T1 (to the left horizontally in FIG. 20A). The mirror 17a is mounted on the slider S3. The slides S1 and S2 are secured to the frame T1.

The location of the rotation axis of the mirror 17a is the intersecting point of the branch beam B1 and the reflection beam B3. When the interference angle θ of the beam B3 is changed to an angle θ′, the normal line from the mirror 17a turns in a desired direction, with the normal line from the mirror 17a keeping equally dividing the angle between the branch beam B1 and the reflection beam B3, as shown in FIG. 20B.

The interference angle θ decided by the mirror 17a is changed to the angle θ′ by a drive unit (actuator) 22. The mirror 17b has the same drive unit as the mirror 17a. One of the drive units 22 is illustrated in FIGS. 20A and 20B. The drive unit 22 applies a force onto a member 24 that extends from the frame T1 along the straight line defined by the reflection beam B3 when the drive unit 22 changes the interference angle θ of the beam B3. It should be noted that the drive unit 22 may directly apply a force onto the frame T1 to change the interference angle θ of the beam B3. The direction of the beam B4 is changed in the same manner by the mirror 17b that is moved by the associated drive unit (not shown).

As described above, the exposure device 1 of this embodiment includes the angle adjustable mirrors 17a and 17b to change the reflecting directions of the beams B1 and B2 (FIG. 19), which are the two branch beams prepared at the beam branching element 6, and direct the reflection beams B3 and B4 toward the substrate or work W such that the two reflection beams B3 and B4 cross each other at a desired angle 2θ′ on the work W. Thus, it is possible to arbitrarily alter the pitch of the stripe pattern (interference pattern) to be formed on the work W. In other words, it is possible to change the pitch of the resist pattern (dot density in the resist pattern) which is obtained upon applying the exposure process a plurality of times.

### Modifications

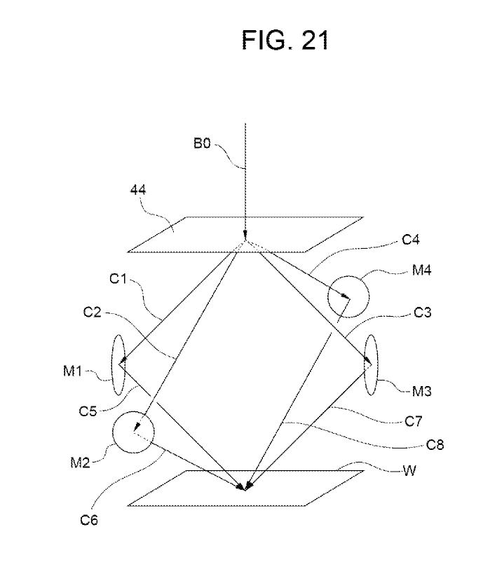

Although the above-described embodiments deal with the two-beam interference exposure, the present invention is not limited in this regard. For example, the beam from the light source may be divided into three or more beams, and these beams may simultaneously be directed to the substrate. In other words, so-called multi-beam interference exposure may be used in the present invention. An optical element for dividing the beam may include a diffracting element that divides, for example, a laser beam into a plurality of beams. For example, if the multi-beam interference exposure should provide the same result as the two-beam interference exposure of the first embodiment, with the angle difference δ between the first interference beam and the second interference beam being 90 degrees, then four beams may be used as shown in FIG. 21. Specifically, a single beam (laser beam) B0 from the light source is divided into four beams C1, C2, C3 and C4 by a beam splitting element 44 in FIG. 21. The beam splitting element 44 may be a diffraction element. The four branch beams C1-C4 are reflected by the associated four mirrors M1, M2, M3 and M4, and become four reflection beams C5, C6, C7 and C8, respectively. The four reflection beams C5-C8 are directed to the work W. The triangle defined by the beam C1, its reflection beam C5 and the normal line from the work W is 90-degree spaced from the triangle defined by the beam C2, its reflection beam C6 and the normal line from the work W when viewed from the top. The triangle defined by the beam C2, its reflection beam C6 and the normal line from the work W is 90-degree spaced from the triangle defined by the beam C3, its reflection beam C7 and the normal line from the work W when viewed from the top. The triangle defined by the beam C3, its reflection beam C7 and the normal line from the work W is 90-degree spaced from the triangle defined by the beam C4, its reflection beam C8 and the normal line from the work W when viewed from the top. The angle defined by the two opposite reflection beams C5 and C7 is 2θ, and the angle defined by the two opposite branch beams C6 and C8 is 2θ. The arrangement of the optical components is decided to satisfy the above-mentioned numerical values.

In the first and second embodiments, the resist pattern is a dot pattern. The present invention is not limited in this regard. For example, if the resist is a negative resist, those portions of the resist which are irradiated with the beams remain in the grid shape after the development, and the resist has a pattern that has a plurality of holes or concaves. The heat treatment, which has been described in the first embodiment, may be applied to the resist pattern that has undergone the development process such that the concaves of the resist pattern are shaped to those concaves which do not have anisotropy.

In the first and second embodiments, the resist pattern that is obtained by the two-beam interference exposure is shaped to a desired pattern by the heat treatment. The present invention is not limited in this regard. For example, the fine pattern which is obtained by a nanoimprint method, a stepper or the like may be shaped to a desired pattern by the heat treatment. For example, the nanoimprint method may be used to obtain the fine pattern having a plurality of convex portions, and the heat treatment is applied to the fine pattern such that the spacing between the adjacent convex portions is reduced to increase the resolution (density). The heat treatment shapes the fine pattern such that the resolution of the fine pattern after the heat treatment becomes greater than the resolution of the fine pattern before the heat treatment.

It is known that a film may be deposited on a surface of a resist pattern by plasma in order to enlarge the width of each convex portion in the resist pattern. This conventional technique may be used to reduce the spacing between the adjacent convex portions in the fine pattern. However, the film deposition over the convex portions may not be carried out precisely because of the distribution of the plasma. On the contrary, the embodiments of the present invention employ the heat treatment. The heat treatment can precisely shape the resist pattern. Therefore, it is possible to appropriately improve the resolution (dot density) of the resist pattern.

The resist pattern may have a line-and-spacing pattern. The heat treatment is applied to the line-and-spacing pattern to change the width of each line in the pattern.

While certain embodiments have been described, these embodiments have been presented by way of example only, and are not intended to limit the scope of the present invention. The novel apparatuses (devices) and methods thereof described herein may be embodied in a variety of other forms; furthermore, various omissions, substitutions and changes in the form of the apparatuses (devices) and methods thereof described herein may be made without departing from the gist of the present invention. The accompanying claims and their equivalents are intended to cover such forms or modifications as would fall within the scope and gist of the present invention.

The present application is based upon and claims the benefit of a priority from Japanese Patent Application No. 2014-244339, filed on Dec. 2, 2014, and the entire contents of which are incorporated herein by reference.

What is claimed is:

1. A method of manufacturing a structure having a first fine pattern on a surface of a substrate or a surface of a functional material layer, the functional material layer being formed on the substrate, the first fine pattern including a plurality of convex portions and/or a plurality of concave portions, the method comprising:
forming a photosensitive material layer on the surface of the substrate or the surface of the functional material layer;
dividing a single beam emitted from a coherent light source into at least two branch beams;
causing the at least two branch beams to cross each other at a predetermined interference angle thereby generating a first interference beam that has a first longitudinal direction;
applying an exposure process to the photosensitive material layer with the first interference beam;
producing a second interference beam from the at least two branch beams such that the second interference beam has a second longitudinal direction, which crosses the first longitudinal direction of the first interference beam at a first predetermined angle, the second interference beam having the predetermined interference angle;
applying the exposure process to the photosensitive material layer with the second interference beam after said applying an exposure process to the photosensitive material layer with the first interference beam;
removing those areas of the photosensitive material layer which are irradiated with the first and second interference beams or removing those areas of the photosensitive material layer which are not irradiated with the first and second interference beams, after the exposure process with the first and second interference beams, thereby forming a second fine pattern in the photosensitive material layer;
applying an etching process to the substrate or the functional material layer with the second fine pattern of the photosensitive material layer, thereby creating the structure having the first fine pattern on the surface of the substrate or the surface of the functional material layer.

2. The method according to claim 1 further comprising, prior to said applying an etching process, applying a heat treatment to the second fine pattern formed in the photosensitive material layer, thereby shaping the second fine pattern to a desired fine pattern.

3. The method according to claim 2, wherein the photosensitive material layer is made from a material having a glass-transition temperature, and said applying a heat treatment includes heating the second fine pattern at a temperature higher than the glass-transition temperature.

4. The method according to claim 1, wherein said producing the second interference beam and said applying the exposure process to the photosensitive material layer with the second interference beam are carried out such that said removing those areas of the photosensitive material layer can form the second fine pattern that has a plurality of convex elements and/or a plurality of concave elements in a square array.

5. The method according to claim 1, wherein said producing the second interference beam and said applying the exposure process to the photosensitive material layer with the second interference beam are carried out such that said removing those areas of the photosensitive material layer can form the second fine pattern that has a plurality of convex elements and/or a plurality of concave elements in a trigonal array.

6. The method according to claim 1 further comprising;
producing another interference beam from the at least two branch beams such that said another interference beam has another longitudinal direction, which crosses the first longitudinal direction of the first interference beam at a second predetermined angle, said another interference beam having the predetermined interference angle; and
applying the exposure process to the photosensitive material layer with said another interference beam after said applying the exposure process to the photosensitive material layer with the second interference beam.

7. The method according to claim 1 further comprising turning the substrate by the first predetermined angle after said applying an exposure process to the photosensitive material layer with the first interference beam and before applying the exposure process to the photosensitive material layer with the second interference beam.

8. The method according to claim 1, wherein the second longitudinal direction of the second interference beam crosses the first longitudinal direction of the first interference beam at 90 degrees.

9. The method according to claim 1, wherein the second longitudinal direction of the second interference beam crosses the first longitudinal direction of the first interference beam at 60 degrees.

10. The method according to claim 1 further comprising applying a sputtering process to the substrate or the functional material layer after said etching process.

11. The method according to claim 1, wherein the first fine structure is a moth eye structure.

12. A method of manufacturing a structure having a first fine pattern on a surface of a substrate or a surface of a functional material layer, the functional material layer being formed on the substrate, the first fine pattern including a plurality of convex portions and/or a plurality of concave portions, the method comprising:
forming a first layer on the surface of the substrate or the surface of the functional material layer;
applying a patterning process to the first layer to form a second fine pattern in the first layer;
applying a heat treatment to the second fine pattern to shape the second fine pattern to a third fine pattern;
applying an etching process to the substrate or the functional material layer with the third fine pattern, thereby creating the structure having the first fine pattern on the surface of the substrate or the surface of the functional material layer.

13. The method according to claim 12, wherein said applying a patterning process to the first layer includes applying a nanoimprint process to the first layer.

14. The method according to claim 12, wherein said applying a patterning process to the first layer includes using a stepper when applying a patterning process to the first layer.

15. The method according to claim 12 further comprising applying a sputtering process to the substrate or the functional material layer after said etching process.

16. The method according to claim 12, wherein the first fine structure is a moth eye structure.

17. A structure on a substrate, which is manufactured by a method of claim 1.
